(19) United States
(12) Patent Application Publication
(10) Pub. No.: US 2026/0162905 A1
(43) Pub. Date: Jun. 11, 2026

(54) ELECTROLYTE OF DYE-SENSITIZED SOLAR CELL AND METHOD FOR MANUFACTURING THE SAME

(71) Applicant: SOOKMYUNG WOMEN'S UNIVERSITY INDUSTRY-ACADEMIC COOPERATION FOUNDATION, Seoul (KR)

(72) Inventors: Young Soo JOUNG, Seoul (KR); YeJin KANG, Seoul (KR); Jee Yoon KIM, Seoul (KR)

(21) Appl. No.: 18/708,022

(22) PCT Filed: Sep. 19, 2022
(86) PCT No.: PCT/KR2022/013940

§ 371 Date: May 7, 2024

(30) Foreign Application Priority Data
Jan. 18, 2022 (KR) 10-2022-0007185

(51) Int. Cl. H01G 9/00; C08J 9/28; C08J 9/40; C08L 33/26; H01G 9/20

(52) U.S. Cl. CPC H01G 9/0036; C08J 9/283; C08J 9/40; C08L 33/26; H01G 9/2009; C08J 2201/0504; C08J 2205/022; C08J 2333/26; C08J 2405/04; C08L 2203/20; C08L 2312/00

(57) ABSTRACT

The present invention relates to an electrolyte for a dye-sensitized solar cell that

have both the advantages of the liquid electrolyte with high ionic conductivity and high power generation efficiency and the advantages of the solid electrolyte with a low risk of leakage, and a manufacturing method thereof. Accordingly, the dye-sensitized solar cell using the hydrogel electrolyte may have both the advantages of the liquid electrolyte with high ionic conductivity and high power generation efficiency and the advantages of the solid electrolyte with the low possibility of leakage.

### TECHNICAL FIELD

The present disclosure relates to an electrolyte of a dye-sensitized solar cell and a manufacturing method thereof, and more specifically, to an electrolyte of a dye-sensitized solar cell using hydrogel and a manufacturing method thereof.

### BACKGROUND ART

Recently, interest in alternative energy sources that may replace existing fossil fuels is rapidly increasing. Among them, solar cells using solar energy are in the spotlight because, unlike other energy sources (such as nuclear energy), the solar energy is infinite and environmentally friendly.

Recently, silicon solar cells have been in the spotlight since the development of Se solar cells in 1983. However, silicon solar cells are very expensive to manufacture, making them difficult to put into practical use. To overcome this problem, research and development is being actively conducted on inexpensive dye-sensitized solar cells.

Unlike the silicon solar cells, the dye-sensitized solar cel is a photoelectrochemical solar cell mainly composed of photosensitive dye molecules that may absorb visible light and generate electron-hole pairs, and a transition metal oxide that transfers the generated electrons. A representative example of the dye-sensitized solar cell known so far is one published by Gratzel et al. in Switzerland.

FIG. 1 is a diagram showing a structure of a conventional dye-sensitized solar cell.

As shown in FIG. 1, a conventional dye-sensitized solar cell 1 includes a working electrode 10, a counter electrode 20 disposed opposite to the working electrode 10, and an electrolyte 30 interposed between the working electrode 10 and the counter electrode 20. A light absorption layer 13 may be disposed on one surface of the working electrode 10, and the light absorption layer 13 may be generally made of a metal oxide 11 such as titanium dioxide (TiO₂) having an adsorbed dye 12 such as cadmium sulfide (CdS) therein.

The dye 12 may exhibit neutral(S), transition state (S*), and ionic state (S+), respectively. When sunlight is absorbed by the dye, the dye molecule undergoes an electronic transition from the ground state (S/S+) to the excited state (S*/S+), thus forming an electron-hole pair. Electrons in an excited state move to the conduction band (CB) of the metal oxide and then diffuse to the working electrode 10, and the electrons that have reached the working electrode 10 pass through an external circuit to the counter electrode 20. In this way, an electromotive force may be generated.

The dye that has lost its electrons by the metal oxide may be reduced by obtaining electrons from the electrolyte 30. In the electrolyte 30, for example, iodide ions are oxidized to iodine to supplement the electrons into the dye, and then, iodine receives electrons that reach the counter electrode 20 and may be reduced back to iodide.

The solar cell operates by repeating the above-described redox process.

The dye-sensitized solar cell as described above is eco-friendly and flexible, has a lower manufacturing cost per power compared to existing silicon cells, and may provide color and ensure transparency at the same time. Thus, the dye-sensitized solar cell may replace the existing solar cells and thus has received attention.

The electrolytes may be divided into liquid electrolytes and solid electrolytes depending on their phases. Liquid electrolyte allows high photoelectric conversion efficiency of the solar cell including the same, but the solvent may leak therefrom depending on a sealing condition or may volatilize due to increased temperature due to solar radiation, resulting in short lifespan and low durability. Solid electrolyte does not have problems with electrolyte leakage or volatilization like the liquid electrolyte, but the solar cell including the same has low photoelectric conversion efficiency of the solar cell including the same because the ionic conductivity of the solid electrolyte is very low, compared to the liquid electrolyte.

Accordingly, there is a need to present necessary technologies to solve the above problems with the liquid electrolytes and the solid electrolytes.

### DISCLOSURE

### Technical Purpose

A purpose of the present disclosure is to provide an electrolyte for a dye-sensitized solar cell that have both the advantages of the liquid electrolyte with high ionic conductivity and high power generation efficiency and the advantages of the solid electrolyte with a low risk of leakage, and a manufacturing method thereof.

### Technical Solution

In order to achieve the purpose, there is provided a method for manufacturing an electrolyte for a dye-sensitized solar cell, the method comprising: preparing a hydrogel molded product; drying the hydrogel molded product; and injecting a liquid electrolyte into the dried hydrogel molded product.

According to one embodiment, the drying of the hydrogel molded product includes heating the hydrogel molded product to form a hydrogel film from which moisture is evaporated.

According to one embodiment, the injecting of the liquid electrolyte includes immersing the dried hydrogel molded product in the liquid electrolyte solution, thereby replacing moisture in the hydrogel molded product with the liquid electrolyte.

According to one embodiment, the liquid electrolyte is an electrolyte solution in which iodine or iodide is dissolved in water as a solvent, wherein the iodide is sodium iodide, potassium iodide, or guanidinium iodide, rather than lithium iodide.

According to one embodiment, the liquid electrolyte further contains guanidinium thiocyanate (GuSCN).

According to one embodiment, the preparing of the hydrogel molded product includes: adding a polymerization initiator and an accelerator to an aqueous solution in which a water-soluble polymer and a crosslinking agent are dissolved, thereby producing a mixed solution; and casting the mixed solution into a mold.

In order to achieve the purpose, there is provided an electrolyte for a dye-sensitized solar cell, wherein the electrolyte is manufactured by drying a hydrogel molded product to remove moisture therefrom to form a hydrogel film, and injecting a liquid electrolyte into the hydrogel film.

In order to achieve the purpose, there is provided a dye-sensitized solar cell comprising: a working electrode; a counter electrode spaced from and facing the working electrode; an electrolyte interposed between the working electrode and the counter electrode; wherein the electrolyte includes the electrolyte for the dye-sensitized solar cell as described above; and a light absorption layer interposed between the working electrode and the electrolyte and including a metal oxide to which a dye has been adsorbed.

### Advantageous Effects

According to the present disclosure, the dye-sensitized solar cell using the hydrogel electrolyte may have both the advantages of the liquid electrolyte with high ionic conductivity and high power generation efficiency and the advantages of the solid electrolyte with a low risk of leakage.

Furthermore, the hydrogel is used as the electrolyte. Thus, the electrolyte has excellent surface adhesion and excellent mechanical strength, which may increase bonding strength of the electrolyte with the electrode, and may have high transparency (or light transmittance) and flexibility.

### DESCRIPTION OF DRAWINGS

FIG. 1 is a diagram showing a structure of a conventional dye-sensitized solar cell.

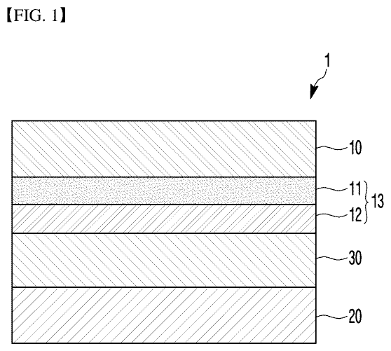

FIG. 2 is a step-by-step flowchart of a manufacturing method of an electrolyte for a dye-sensitized solar cell according to one embodiment of the present disclosure.

FIG. 3 is a photograph showing a hydrogel film produced according to one embodiment of the present disclosure and a state in which a liquid electrolyte is injected into the film.

FIG. 4 is a photograph showing a hydrogel film produced according to one embodiment of the present disclosure.

FIG. 5 is a diagram showing an efficiency of a dye-sensitized solar cell using a hydrogel film produced according to one embodiment of the present disclosure as an electrolyte.

FIG. 6 is a diagram showing an efficiency of a dye-sensitized solar cell when a hydrogel produced according to a conventional manufacturing method is used as an electrolyte.

FIG. 7 is a diagram showing a power conversion efficiency based on a thickness of a hydrogel film produced according to one embodiment of the present disclosure.

### BEST MODE

The present disclosure will be described in detail below through preferred embodiments. Prior to this description, the terms and words used herein and claims should not be construed as limited to their usual or dictionary meanings. Rather, based on the principle that an inventor may appropriately define the concept of the term in order to describe his or her invention in the best way, the terms and words used herein and claims should be interpreted as meaning and concept consistent with the technical idea of the present disclosure. Therefore, a configuration of the embodiment as described in the present disclosure is only one of the most desirable embodiments of the present disclosure and does not represent all of the technical ideas of the present disclosure. It should be understood that at the time of filing the present application, there may be various equivalents and modifications that may replace the embodiments. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof.

Manufacturing method of electrolyte for dye-sensitized solar cell

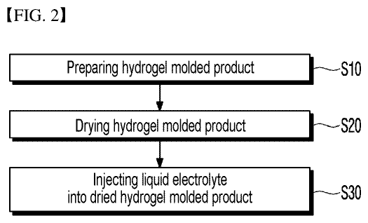

FIG. 2 is a step-by-step flowchart of a manufacturing method of an electrolyte for a dye-sensitized solar cell according to one embodiment of the present disclosure.

As shown in FIG. 2, the manufacturing method of the electrolyte for the dye-sensitized solar cell according to one embodiment of the present disclosure may include preparing a hydrogel molded product in S10, drying the hydrogel molded product in S20, and injecting a liquid electrolyte into the dried hydrogel molded product in S30, thereby producing the electrolyte for the dye-sensitized solar cell.

In other words, the electrolyte for the dye-sensitized solar cells according to the present disclosure is manufactured by preparing the hydrogel molded product, drying the same to remove moisture therefrom, and then filling the same with the liquid electrolyte to produce the electrolyte in a form of a thin film.

In the step of preparing the hydrogel molded product in S10, the molded product may be prepared by molding a hydrogel according to a known composition or a known manufacturing method. However, according to one embodiment of the present disclosure, the hydrogel molded product may have a form such as a thin film or sheet so that it may be used as an electrolyte for a dye-sensitized solar cell. However, the scope of the present disclosure is not limited thereto.

However, according to one embodiment of the present disclosure, the hydrogel molded product may be formed by adding a polymerization initiator and an accelerator to an aqueous solution in which a water-soluble polymer and a cross-linking agent are dissolved in water to prepare a mixed solution and casting the mixed solution into a mold, such that the hydrogel molded product as the electrolyte for the dye-sensitized solar cell has excellent surface adhesion and mechanical strength and high light transmittance and high flexibility.

In this regard, the water-soluble polymer may be one selected from the group consisting of alginic acid, chitosan, alginate, dextran, oxidized dextran, heparan, heparin, hyaluronic acid, agarose, carageenan, amylopectin, amylose, glycogen, starch, cellulose, chitin, heparan sulfate, chondroitin sulfate, dextran sulfate, dermatan sulfate, keratan sulfate, pectins, xanthan gum, carboxymethyl cellulose, homo and copolymers of acrylamide, polyacrylic acid, polyethylene oxide, polyvinyl alcohol, polyvinyl alcohol-polyvinylacetate copolymer, poly(N-vinylpyrrolidone), polyhydroxyethyl acrylate or a combination thereof. Such natural and synthetic water-soluble polymers preferably have an average molecular weight of 100 to 1,000,000, more preferably 700 to 200,000.

According to one specific embodiment, acrylamide and sodium alginate may be dissolved in water (or deionized water), wherein water, acrylamide, and sodium alginate may be contained in contents of 80 to 90 parts by weight, 10 to 15 parts by weight, and 0.01 to 0.5 parts by weight, respectively, more preferably, water, acrylamide and sodium alginate may be contained in contents of 85 to 90 parts by weight, 12 to 13 parts by weight, and 0.4 to 0.5 parts by weight, respectively.

In this regard, the content of water is preferably 80 to 90 parts by weight, as described above. When the water content is smaller than 80 parts by weight, the hygroscopicity of the hydrogel becomes stronger, and the hydrogel may deteriorate over time. Additionally, when the water content exceeds 80 parts by weight, drying may cause shrinkage of the adhesive hydrogel or change in physical properties.

Thereafter, the polymerization initiator and the crosslinking agent may be added to the aqueous solution.

The polymerization initiator may be a photo-radical polymerization initiator or a thermal radical polymerization initiator. In this regard, the photo-radical polymerization initiator is not particularly limited. Examples thereof may include α-hydroxyketone, α-aminoketone, benzylmethyl ketal, bisacylphosphine oxide, metallocene, etc. More specifically, the photo-radical polymerization initiator may be 1-[4-(2-hydroxyethoxy)-phenyl]-2-hydroxy-2-methyl-propan-1-one, 2-hydroxy-2-methyl-1-phenyl-propane-1-one, 1-hydroxy-cyclohexyl-phenyl-ketone, 2-methyl-1-[(methylthio)phenyl]-2-morpholinopropan-1-one, 2-benzyl-2-dimethylamino-1-(4-morpholinophenyl)-butan-1-one, etc. These photo-radical initiators may be used individually, or two or more types thereof may be combined with each other.

Furthermore, the thermal radical polymerization initiator is also not particularly limited, and examples thereof may include organic peroxides such as benzoyl peroxide, azo-based polymerization initiators such as azobisisobutyronitrile, persulfates such as potassium persulfate and ammonium persulfate, and an azo compound such as 2,2-azobisamidinopropane dihydrochloride.

According to one embodiment of the present disclosure, the content of the polymerization initiator is not particularly limited, but is preferably in a range of 0.01 to 1 part by weight based on a total weight of the aqueous solution of acrylamide and sodium alginate. When the content of the polymerization initiator is smaller than 0.01 parts by weight, the polymerization reaction does not proceed sufficiently. When the content of the polymerization initiator exceeds 1 part by weight, the resulting hydrogel may discolor (yellow) or may have a foul odor due to the residue of the polymerization initiator after the polymerization reaction.

More preferably, the polymerization initiator content may be in a range of 0.05 to 0.5 parts by weight.

Furthermore, in addition to the polymerization initiator, a cross-linking agent may be added to the aqueous solution. The cross-linking agent is not particularly limited. However, according to one preferred embodiment, N,N′-methylenebisacrylamide as the cross-linking agent may be used and dissolved in the aqueous solution.

The type of the crosslinking agent is not particularly limited, but it is preferable that the cross-linking agent has two or more double bonds having a polymerization ability in the molecule. Examples thereof may include N,N′-methylenebisacrylamide, diethylene glycol diacrylate and dimethacrylate, ethylene glycol diacrylate and dimethacrylate, tetra(ethylene glycol) diacrylate, 1,6-hexanediol diacrylate, divinylbenzene, trimethylolpropane triacrylate, and poly(ethylene glycol) diacrylate. The compounds may be used alone or in combination of two or more thereof.

According to one embodiment of the present disclosure, the content of the cross-linking agent may be in a range of 0.001 to 0.05 parts by weight, more preferably 0.0015 to 0.02 parts by weight, based on a total weight of the aqueous solution of acrylamide and sodium alginate.

Thereafter, degassing may be performed on the aqueous solution of acrylamide and sodium alginate to which ammonium persulfate as a polymerization initiator and N,N′-methylenebisacrylamide as a crosslinking agent have been added. This is because when the aqueous solution contains bubbles, the mechanical strength of the formed hydrogel decreases.

According to one specific embodiment, the aqueous solution may be placed in a vacuum chamber which may be then evacuated. Regardless of the evacuation time or the remaining air pressure inside the vacuum chamber, it may suffice that bubbles in the aqueous solution is removed, or bubbles are attached to a wall of a container containing the aqueous solution. However, the degassing process may be omitted when no bubbles are produced when mixing the solution.

Afterwards, an accelerator as a catalyst added to increase the reaction rate may be added to the aqueous solution.

The accelerator is also not particularly limited. according to a preferred embodiment, N, N, N′, N′-tetramethylenediamine may be used as the accelerator and dissolved in the aqueous solution.

According to one embodiment of the present disclosure, the content of the accelerator is not particularly limited, but may be in a range off 0.01 to 0.05 parts by weight, preferably 0.03 to 0.04 parts by weight, relative to the total weight of the aqueous solution of acrylamide and sodium alginate.

Since gelation may occur quickly after dissolving the accelerator therein, the mixed solution may be added to the mold and casted within about 3 minutes after dissolving the accelerator therein, thereby obtaining the molded hydrogel.

Specifically, the hydrogel film may be formed to an arbitrary thickness by putting the aqueous solution in the mold (acrylic or glass, etc.), At this time, in order to use the molded product as the electrolyte for the dye-sensitized solar cell, it is preferable to mold the same into a hydrogel film (or sheet) with a thickness of 0.5 to 2 mm, preferably 1 mm (see Experimental Example 2 below).

However, when the hydrogel film is manufactured so as to have a large thickness, the amount or density of the ion injection may be increased in a corresponding manner to the increased thickness, and thus electron transfer and efficiency may be increased (see FIG. 8).

In one example, heating may be performed to promote the gelation reaction under the accelerator. In this regard, the UV light may be irradiated to promote the reaction of N,N,N′,N′-tetramethylenediamine during the heat treatment process.

The heat treatment process may be performed in a dryer at 30 to 60° C. for 0.5 to 5 hours, preferably at 50° C. for 1 to 3 hours. During the heat treatment process, the UV light may be irradiated to promote the reaction of N, N,N′,N′-tetramethylenediamine during the heat treatment process.

However, it is preferable that the heat treatment process according to one embodiment of the present disclosure is performed in a state in which the mold is not sealed and only a lid covers the mold.

Next, the hydrogel molded product formed through step S10 may be dried in S20.

The drying step in S20 may be performed by heat treatment in a dryer at 30 to 60° C., preferably 50° C., for 1 to 4 days to entirely evaporate the moisture in the hydrogel molded product. The drying time required to entirely evaporate moisture may vary depending on the thickness of the hydrogel. However, it is desirable to dry sufficiently the same to entirely dry the moisture in the hydrogel molded product.

In this regard, it is preferable that the mold containing the hydrogel molded product is also dried in a state in which the mold is not sealed and only a lid covers the mold.

The hydrogel molded product from which the moisture has evaporated in this way may be present in a form of a thin film.

Afterwards, the liquid electrolyte may be injected into the entirely dried film-type hydrogel molded product in S30.

In order to inject the liquid electrolyte into the film-type hydrogel molded product (abbreviated as “hydrogel film” in the present disclosure), various known methods may be performed. However, according to one embodiment of the present disclosure, the hydrogel film may be immersed in the liquid electrolyte.

Immersing the hydrogel film in the liquid electrolyte may allow the liquid electrolyte to be permeated into the hydrogel film. Ultimately, the moisture in the hydrogel molded product molded in step S10 is replaced with the liquid electrolyte, such that the electrolyte with the high ionic conductivity of the liquid electrolyte may be manufactured while maintaining the adhesiveness of the hydrogel.

In the process of injecting the liquid electrolyte, the liquid electrolyte in which the hydrogel molded product is immersed may be maintained in a sealed state while the light is blocked to prevent iodine and moisture from evaporating, and may be left at room temperature for 1 to 3 days.

According to one embodiment of the present disclosure, in the liquid electrolyte that replaces the moisture in the hydrogel molded product, water rather than an organic solvent may be used as a solvent to reduce a manufacturing cost thereof and reduce toxicity.

Specifically, the liquid electrolyte according to one embodiment of the present disclosure may be an electrolyte solution containing iodine and/or iodide using water as a solvent. The concentration of iodine dissolved in water (or deionized water) may be preferably in a range of 10 mM to 80 mM, or the concentration of iodide dissolved in water (or deionized water) may be in a range of 0.5 to 8 M.

This is because when the concentration of iodine or iodide is smaller than 0.01 M, there is a problem of low electrolyte conductivity.

However, when iodine is dissolved in a non-polar solvent, the solubility thereof is very high compared to the case in which iodine is dissolved in the water used as the solvent. When iodine is dissolved in other organic solvents such as methanol and ethanol, the solubility thereof is very high compared to the case in which iodine is dissolved in the water used as the solvent. However, in order to ensure the safety and reliability of the dye-sensitized solar cell, the water may be used as the main solvent.

The iodide preferably contains a compound having an iodide ion as a counter ion and thus capable of releasing iodide ions. The compound having the iodide ion as the counter ion is not particularly limited as long as it is a compound that may provide iodide ions into the solution. However, a compound with a high dissociation level of iodide ions is preferred.

In a specific example, the compound having the iodide ion as the counter ion may include lithium iodide (LiI), sodium iodide (NaI), potassium iodide (KI), guanidinium iodide (GuI), trimethylammonium iodide, tetrabutylammonium iodide, 1,3-dimethylimidazolium iodide, 1-ethyl-3-methylimidazolium iodide, 1-methyl-3-propylimidazolium iodide, 1-butyl-3-methylimidazolium iodide, and 1,2-dimethyl-3-propylimidazolium iodide. These compounds may be used alone or in combination of two or more thereof.

However, when using the water as a solvent, the iodide that may release the iodide ions may include one of sodium iodide (NaI), potassium iodide (KI), guanidinium iodide (GuI) or a combination thereof rather than lithium iodide (LiI). In other words, power generation efficiency and durability may be improved by using water rather than an organic solvent as a solvent and applying the iodide suitable for the water as the solvent.

To promote dissolution of iodine and/or iodide in water, the mixed solution may be heated to 30 to 50° C. using a heating device such as a hot plate, or mixed using a magnetic bar. However, when dissolving the iodine and/or iodide in water, it is desirable to mix the mixed solution in a sealed container while blocking light.

In this way, light should be blocked when preparing the liquid electrolyte. When light is blocked and the container is sealed in preparing the liquid electrolyte, long-term use of the liquid electrolyte and the hydrogel electrolyte impregnated with the liquid electrolyte may be achieved.

When preparing and storing the liquid electrolyte, the liquid electrolyte may be stored at room temperature while blocking light and blocking the inflow of external air. However, before immersing the hydrogel film in the liquid electrolyte, a magnetic bar may be used to disperse the liquid electrolyte for 1 to 5 minutes.

In one example, according to one embodiment of the present disclosure, it is desirable to additionally dissolve 0.4 to 0.6 M, preferably 0.5 M, of guanidinium thiocyanate (GuSCN) in the liquid electrolyte. This is because the guanidinium cation of guanidinium thiocyanate (GuSCN) is adsorbed to the oxide semiconductor, improving the performance of the dye-sensitized solar cell and increasing the electron transfer speed, thereby increasing the short-circuit current density (J_{sc}).

In this way, according to one embodiment of the present disclosure, when the liquid electrolyte has been injected into the entirely dried film-type hydrogel molded product, a thickness of the completed hydrogel may be in a range of 500 to 600 μm. When manufacturing the dye-sensitized solar cell using the completed hydrogel as the electrolyte, a thickness of the compressed hydrogel may be in a range of 60 to 70 μm.

Hereinafter, the present disclosure is described in more detail based on examples of the present disclosure, but the scope of the present disclosure is not limited by the examples presented below.

### Example 1

Deionized water, acrylamide, and sodium alginate were prepared in contents of 87.4 parts by weight, 12.19 parts by weight, and 0.41 parts by weight, respectively. After dissolving acrylamide and sodium alginate in deionized water to prepare the mixed solution, 0.12 parts by weight of ammonium persulfate and 0.018 parts by weight of N,N′-methylenebisacrylamide relative to a total weight of the solution were further dissolved in the mixed solution. Then, the solution was maintained in the vacuum chamber until bubbles in the solution were removed therefrom.

0.034 parts by weight of N,N,N′,N′-tetramethylenediamine based on a total wight of the mixed solution of deionized water, acrylamide, and sodium alginate was added to the vacuumized solution. Before curing, 6 mL thereof was poured into a circular Petri dish with a diameter of 150 mm and a height of 20 mm, and heat treatment was performed thereon in a dryer at 50° C. for 24 hours. In this regard, the Petri dish was not sealed and only the lid was closed during the heat treatment process.

On the other hand, in order to dissolve iodine at a concentration of 0.02 M, potassium iodide at a concentration of 4 M, and guanidinium thiocyanate at a concentration of 0.5 M in 200 mL of deionized water, first the iodine, potassium iodide, and guanidinium thiocyanate were dissolved in 200 mL of deionized water to prepare a solution, which in turn was dispersed via stirring using a magnetic bar for 30 minutes in a sealed bottle and in a light blocked state. Deionized water was additionally poured thereto until an amount of the liquid electrolyte reached 200 mL, sealed again, maintained in a sealed state, and stirred for 3 to 4 hours using a magnetic bar to prepare the liquid electrolyte.

The hydrogel molded product completed through the previous heat treatment process was left in a dryer at 50° C. for 1 to 4 days while the Petri dish was not sealed and only the lid was closed, thereby entirely evaporating the moisture therefrom. The thin hydrogel film from which the moisture was entirely removed was entirely submerged into the liquid electrolyte as prepared above such that 6 to 10 mL of the liquid electrolyte prepared above was injected into the film. The film was stored in a sealed state and in a light blocked state at room temperature for 1 to 3 days.

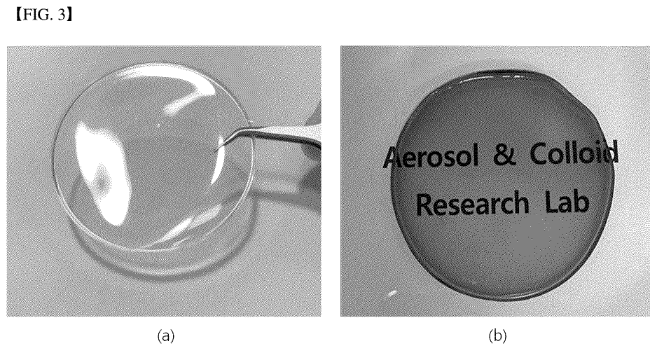

(a) in FIG. 3 is a diagram showing a hydrogel film from which moisture has been removed, and (b) in FIG. 3 is a diagram showing a state in which the hydrogel film is injected with liquid electrolyte.

### Example 2

The hydrogel film was produced in the same manner as in Example 1 above, except that the liquid electrolyte was prepared with iodine at a concentration of 0.03 M.

### Experimental Example 1

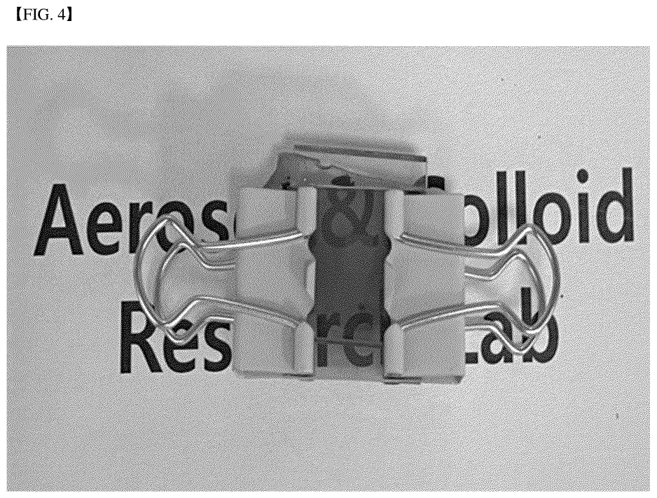

The hydrogel prepared according to each of Examples 1 and 2 above had a thickness of 500 to 600 μm, and was applied to a dye-sensitized solar cell (see FIG. 4). At this time, the electrolyte was compressed to a thickness of 60 to 70 μm.

In this regard, the working electrode of the dye-sensitized solar cell to which the electrolyte was prepared by spin-coating 18NR-T TiO₂ paste and then heat treating the coating using a hot plate. The counter electrode thereof was prepared by sputter coating Pt. N-719 was used as the dye of the solar cell. Measurement was based on 1 sun (100 mA/cm₂).

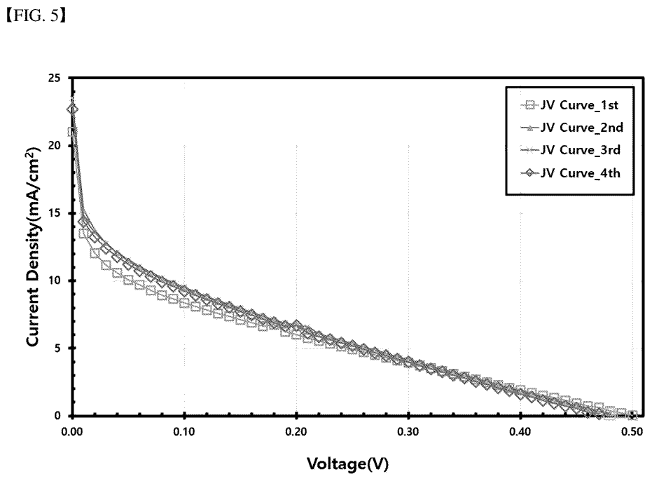

Accordingly, the power conversion efficiency (PCE) was measured, and the resulting efficiency is shown in FIG. 5.

### Comparative Example 1

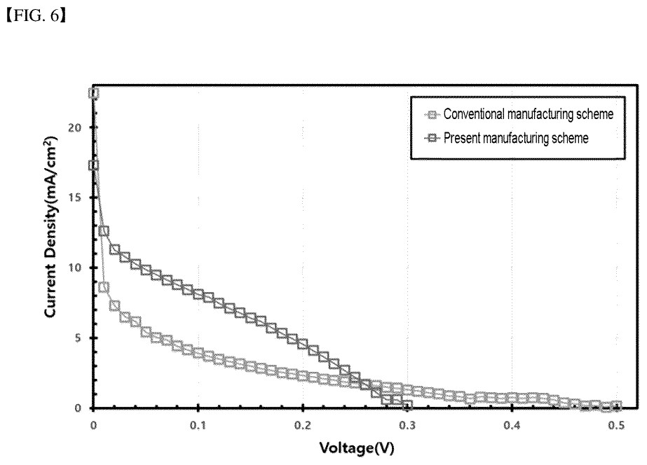

Unlike Example 1 above, the hydrogel molded product was prepared conventionally, immersed in a liquid electrolyte solution, and then used as an electrolyte for a dye-sensitized solar cell. The measured power conversion efficiency is shown in FIG. 6. As shown, the power conversion efficiency thereof was found to be 0.461055%.

In conclusion, it may be identified based on a comparing result between the power conversion efficiency of the conventional Comparative Example 1 and the power conversion efficiency of each of Examples 1 and 2, the power conversion efficiency of each of Examples 1 and 2 is at least two times higher than the power conversion efficiency of the conventional Comparative Example 1.

### Example 3

The hydrogel film was produced in the same manner as in Example 1 above, except that the hydrogel molded product was molded in a mold so as to have a thickness of 1.76 mm.

### Example 4

The hydrogel film was produced in the same manner as in Example 1 above, except that the hydrogel molded product was molded in a mold so as to have a thickness of 0.51 mm.

### Experimental Example 2

Each of the electrolytes prepared according to Examples 3 and 4 were applied to a dye-sensitized solar cell as in Experimental Example 1.

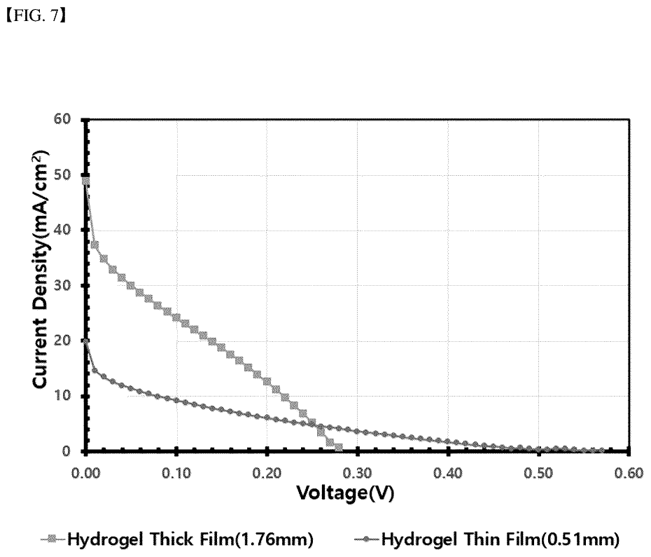

The power conversion efficiency according to each of Examples 3 and 4 was measured four times. The measured power conversion efficiencies were averaged. Thus, the average power conversion efficiencies as calculated in Examples 3 and 4 were 2.79% and 1.20%, respectively, (FIG. 7).

### Manufacturing Method of Dye-Sensitized Solar Cell

The electrolyte of the dye-sensitized solar cell as manufactured according to one embodiment of the present disclosure has surface adhesion. Thus, the electrolyte for the dye-sensitized solar cell manufactured according to one embodiment of the present disclosure is interposed between the working electrode 10 and the counter electrode 20 manufactured according to a known method. The working electrode 10 and the counter electrode 20 were pressed against each other such that the dye-sensitized solar cell 1 may be manufactured.

In this regard, the working electrode 10 may include a substrate and a conductive material (for example, TiO₂, CNT, etc.) coated thereon. The light absorption layer 13 may be disposed on the working electrode 10 and may include a metal oxide layer 11 coated on one surface of the working electrode 10 and the dye 12 (for example, N-719,etc.) adsorbed on the metal oxide layer.

The preferred embodiment of the present disclosure has been described above in detail with reference to the drawings. The description of the present disclosure is for illustrative purposes. A person with ordinary knowledge in the technical field to which the present disclosure belongs may understand that the present disclosure may be easily modified into another specific form without changing the technical idea or essential features of the present disclosure.

Therefore, the scope of the present disclosure is indicated by the patent claims described later rather than the detailed description above, and all changes or modified forms derived from the meaning, scope, and equivalent concept of the claims should be interpreted as being included in the scope of the present disclosure.

1. A method for manufacturing an electrolyte for a dye-sensitized solar cell, the method comprising:
preparing a hydrogel molded product;
drying the hydrogel molded product; and
injecting a liquid electrolyte into the dried hydrogel molded product.

2. The method of claim 1, wherein the drying of the hydrogel molded product includes heating the hydrogel molded product to form a hydrogel film from which moisture is evaporated.

3. The method of claim 1, wherein the injecting of the liquid electrolyte includes immersing the dried hydrogel molded product in the liquid electrolyte solution, thereby replacing moisture in the hydrogel molded product with the liquid electrolyte.

4. The method of claim 1, wherein the liquid electrolyte is an electrolyte solution in which iodine or iodide is dissolved in water as a solvent,
wherein the iodide is sodium iodide, potassium iodide, or guanidinium iodide, rather than lithium iodide.

5. The method of claim 4, wherein the liquid electrolyte further contains guanidinium thiocyanate (GuSCN).

6. The method of claim 1, wherein the preparing of the hydrogel molded product includes:
adding a polymerization initiator and an accelerator to an aqueous solution in which a water-soluble polymer and a crosslinking agent are dissolved, thereby producing a mixed solution; and
casting the mixed solution into a mold.

7. An electrolyte for a dye-sensitized solar cell, wherein the electrolyte is manufactured by drying a hydrogel molded product to remove moisture therefrom to form a hydrogel film, and injecting a liquid electrolyte into the hydrogel film.

8. A dye-sensitized solar cell comprising:
a working electrode;
a counter electrode spaced from and facing the working electrode;
an electrolyte interposed between the working electrode and the counter electrode;
wherein the electrolyte includes the electrolyte for the dye-sensitized solar cell of claim 7; and
a light absorption layer interposed between the working electrode and the electrolyte and including a metal oxide to which a dye has been adsorbed.
